(19) United States
(12) Patent Application Publication
(10) Pub. No.: US 2024/0038960 A1
(43) Pub. Date: Feb. 1, 2024

(54) DISPLAY BACKPLANE AND DISPLAY DEVICE

(71) Applicant: SUZHOU CHINA STAR OPTOELECTRONICS TECHNOLOGY CO., LTD., Suzhou, Jiangsu (CN)

(72) Inventors: Qiong LIU, (US); Lu CHEN, (US); Junjie LI, (US); Dan CAO, (US)

(21) Appl. No.: 17/904,004

(22) PCT Filed: Aug. 8, 2022
(86) PCT No.: PCT/CN2022/110826

§ 371 Date: Aug. 10, 2022

(30) Foreign Application Priority Data
Jul. 28, 2022 (CN) 202210901017.9

(51) Int. Cl. H01L 33/64; H01L 25/075

(52) U.S. Cl. CPC H01L 33/642; H01L 25/0753

(57) ABSTRACT

The present disclosure provides a display backplane and a display device, the display backplane includes a backplane layer, a substrate layer, a heat conductive layer, a light-emitting layer, and heat conductive holes at least penetrating through the substrate layer, which are stacked and arranged. Heat dissipation columns are arranged in the heat conductive holes, and the heat dissipation columns are in contact with the heat conductive layer.

### FIELD OF INVENTION

The present disclosure relates to a field of display, and particularly relates to a display backplane and a display device.

### BACKGROUND OF INVENTION

An existing light-emitting diode display backplane generally includes a driving circuit board and light-emitting diodes located on the driving circuit board, for example, micro light-emitting diodes (micro-LEDs) or mini light-emitting diodes (mini-LEDs).

A current display backplane is generally bonded with a backplane by a heat dissipation glue to export heat in the display backplane through the backplane. However, since a substrate in the display backplane bonded with the heat dissipation glue is an insulating substrate with poor heat conductivity, heat emitted by light-emitting units in the display backplane may not be effectively conducted into the heat dissipation glue, resulting in a poor heat dissipation effect of the display backplane.

Therefore, a display backplane is urgently needed to solve above-mentioned technical problems.

### Technical Problems

The present disclosure provides a display backplane and a display device to solve technical problems of a poor heat dissipation effect of existing display backplanes.

### Technical Solutions

The present disclosure provides a display backplane, including:
a substrate layer;
a heat conductive layer arranged on a surface of the substrate layer;
a light-emitting layer arranged on a surface of the heat conductive layer;
a backplane layer arranged on a side of the substrate layer away from the heat conductive layer; and
heat conductive holes at least penetrating through the substrate layer, heat dissipation columns are arranged in the heat conductive holes, and the heat dissipation columns are in contact with the heat conductive layer and the backplane layer, respectively.

The present disclosure further provides a display device, the display device includes a display backplane and a cover layer arranged on the display backplane; wherein the display backplane includes:
a substrate layer;
a heat conductive layer arranged on a surface of the substrate layer;
a light-emitting layer arranged on a surface of the heat conductive layer;
a backplane layer arranged on a side of the substrate layer away from the heat conductive layer; and
heat conductive holes at least penetrating through the substrate layer, heat dissipation columns are arranged in the heat conductive holes, and the heat dissipation columns are in contact with the heat conductive layer and the backplane layer, respectively.

### Beneficial Effects

In the present disclosure, heat conductive holes are arranged on a substrate layer, and heat dissipation columns are filled in the heat conductive holes to make heat in a heat conductive layer be conducted to a backplane layer through the heat dissipation columns in the heat conductive holes, improving heat dissipation efficiency of a display backplane.

### DESCRIPTION OF DRAWINGS

FIG. 1 is a first structural diagram of a display backplane of the present disclosure.

FIG. 2 is a structural diagram of an array driving layer in the display backplane of the present disclosure.

FIG. 3 is a second structural diagram of the display backplane of the present disclosure.

FIG. 4 is a third structural diagram of the display backplane of the present disclosure.

FIG. 5 is a fourth structural diagram of the display backplane of the present disclosure.

FIG. 6 is a fifth structural diagram of the display backplane of the present disclosure.

FIG. 7 is a sixth structural diagram of the display backplane of the present disclosure.

### DETAILED DESCRIPTION OF EMBODIMENTS

Purposes and technical solutions of the present disclosure and the effects thereof will be described in detail in the following with reference to exemplary embodiments and the corresponding accompanying drawings. It should be understood that the specific embodiments described herein are merely for explaining the present disclosure, and the present disclosure is not limited thereto.

An existing display backplane is generally bonded with a backplane by a heat dissipation glue to export heat in the display backplane through the backplane. However, since a substrate bonded with the heat dissipation glue is an insulating substrate with poor heat conductivity, heat emitted by light-emitting units in the display backplane may not be effectively conducted into the heat dissipation glue, resulting in a poor heat dissipation effect of the display backplane.

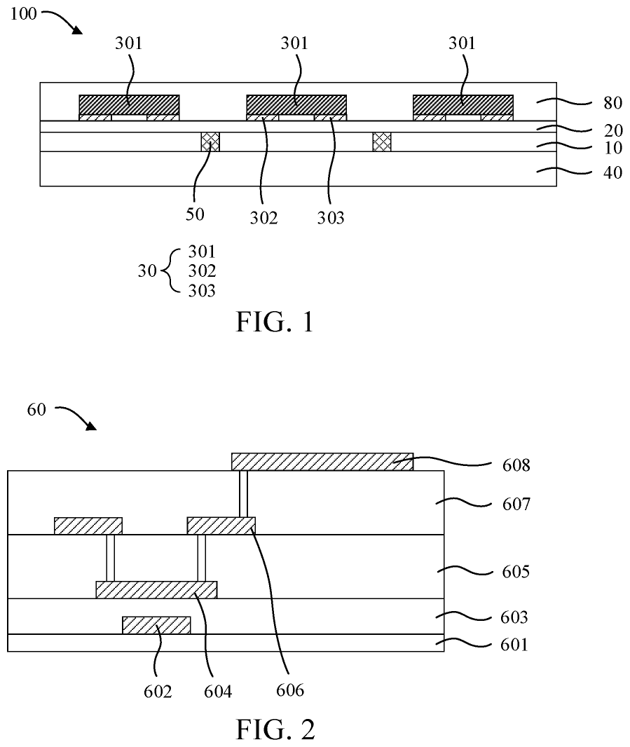

Referring to FIG. 1 to FIG. 3, the present disclosure provides a display backplane 100 including a substrate layer 10, a heat conductive layer 20 arranged on a surface of the substrate layer 10, a light-emitting layer 30 arranged on a surface of the heat conductive layer 20, and a backplane layer 40 arranged on a side of the substrate layer 10 away from the heat conductive layer 20.

In this embodiment, the display backplane 100 further includes heat conductive holes 50 at least penetrating through the substrate layer 10, heat dissipation columns are arranged in the heat conductive holes 50, and the heat dissipation columns are in contact with the heat conductive layer 20 and the backplane layer 40, respectively.

In the present disclosure, the heat conductive holes 50 are arranged on the substrate layer 10, and the heat dissipation columns are filled in the heat conductive holes 50, heat emitted by the light-emitting layer 30 in the display backplane 100 is conducted to the backplane layer 40 through the heat conductive layer 20. Through an arrangement of the heat conductive holes 50, heat in the heat conductive layer 20 may be conducted to the backplane layer 40 through the heat dissipation columns in the heat conductive holes 50, improving heat dissipation efficiency of the display backplane 100.

It should be noted that the heat dissipation columns may be a heat curing insulating glue cured by ultraviolet light.

It should be noted that the substrate layer 10 may be arranged in contact with the backplane layer 40, and other heat conductive materials may also be arranged between the substrate layer 10 and the backplane layer 40, which is not limited here.

The technical solutions of the present disclosure are described in combination with specific embodiments.

In this embodiment, the display backplane 100 may be used as a backlight module, that is, the display backplane 100 may be combined with a liquid crystal display panel to form a liquid crystal display module; or, the display backplane 100 may be used as a device for direct display.

Referring to FIG. 1, the display backplane 100 may include the backplane layer 40, the substrate layer 10, the heat conductive layer 20, an array driving layer 60, the light-emitting layer 30, and a protective layer 80 covering the light-emitting layer 30, which are arranged in a stack. The array driving layer 60 is arranged on a surface of the heat conductive layer 20.

In this embodiment, a material of the backplane layer 40 may include carbon fiber and resin.

In this embodiment, the material of the backplane layer 40 may further include a curing agent, a diluent, and a toughening agent. The backplane is formed by using carbon fiber, resin, the curing agent, the diluent, and the toughening agent; while improving heat conductivity and an electromagnetic shielding performance of the backplane and reducing a thickness and a weight of the backplane, the backplane has a certain toughness to improve anti-extrusion and impact resistance of an organic light-emitting diode (OLED) display module.

In this embodiment, the material of the backplane layer 40 may further include nickel, the curing agent, the diluent, and the toughening agent; when forming the backplane, nickel plating may also be performed to improve an electromagnetic shielding effect of the backplane.

In this embodiment, the heat conductive layer 20 may be made of metals with good heat conductivity such as copper and aluminum.

In this embodiment, a material of the substrate layer 10 may be glass, quartz, or polyimide, etc.; for example, when the display backplane 100 is a flexible backplane, the material of the substrate layer 10 may be composed of flexible materials such as polyimide, etc., or a laminated film layer of the flexible materials and inorganic materials. When the display backplane 100 is an inflexible backplane, the material of the substrate layer 10 may be composed of glass, quartz, or other inorganic insulating materials.

In this embodiment, the array driving layer 60 may include a plurality of thin film transistors, each of the thin film transistors may be an etching barrier type or a back channel etching type, or, may be divided into a structure of a bottom gate thin film transistor or a top gate thin film transistor, etc., according to a position of a gate electrode and an active layer, and the details are not limited.

For example, the thin film transistor shown in FIG. 2 is a top-gate type thin film transistor, the thin film transistor may include a buffer layer 601 arranged on the heat conductive layer 20, a gate electrode layer 602 arranged on the buffer layer 601, a gate insulating layer 603 arranged on the gate electrode layer 602, an active layer 604 arranged on the gate insulating layer 603, an interlayer insulating layer 605 arranged on the active layer 604, a source-drain electrode layer 606 arranged on the interlayer insulating layer 605, a planarization layer 607 arranged on the source-drain electrode layer 606, and a first electrode layer 608 arranged on the planarization layer 607.

In this embodiment, referring to FIG. 1, the light-emitting layer 30 may include a plurality of light-emitting units 301, the light-emitting units 301 may be micro light-emitting diodes or mini light-emitting diodes. First electrode terminals 302 of the light-emitting units 301 are electrically connected to the first electrode layer 608, and second electrode terminals 303 of the light-emitting units 301 are electrically connected to a second electrode layer, and the second electrode layer (not shown) is connected to a constant voltage source.

In the display backplane 100 of the present disclosure, the light-emitting layer 30 may include a plurality of lamp areas, a plurality of the light-emitting units 301 arranged in an array are arranged in each of the lamp areas, and at least one of the heat conductive holes 50 may be arranged in each of the lamp areas.

In this embodiment, for large-sized panels, a number of the light-emitting units 301 is larger, therefore, the light-emitting layer 30 needs to be partitioned and arranged; for example, each of the lamp areas may include 12 of the light-emitting units 301 distributed in 3*4.

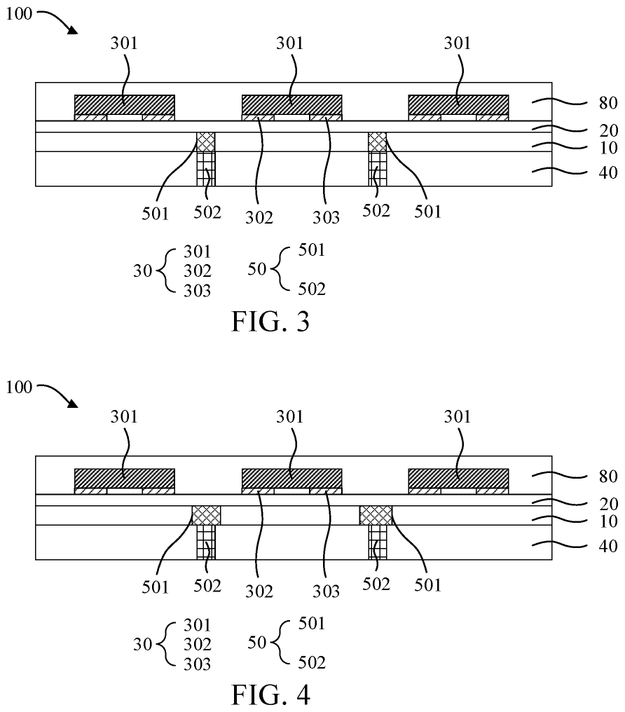

In the display backplane 100 of the present disclosure, referring to FIG. 3, the heat conductive holes 50 include first sub-holes 501 and second sub-holes 502, and the first sub-holes 501 and the second sub-holes 502 are continuously arranged. The first sub-holes 501 are defined in the substrate layer 10, and the second sub-holes 502 are defined in the backplane layer 40.

In this embodiment, the first sub-holes 501 are in the substrate layer 10, and the first sub-holes 501 are butted with the second sub-holes 502; the heat in the heat conductive layer 20 is conducted to the heat dissipation columns in the second sub-holes 502 through the first sub-holes 501, and the heat is conducted to the backplane layer 40 through the heat dissipation columns in the second sub-holes 502.

In this embodiment, a thermal conductivity of each of the heat dissipation columns in the second sub-holes 502 is greater than a thermal conductivity of the backplane layer 40. The first sub-holes 501 are butted with the second sub-holes 502, and the thermal conductivity of each of the heat dissipation columns in the second sub-holes 502 is greater than the thermal conductivity of the backplane layer 40, accelerating an exchange of heat in the first sub-holes 501 to the second sub-holes 502.

Compared with the structure in FIG. 1, although the backplane layer 40 has certain heat conductivity, however, the heat conductivity is limited. The heat conductive holes 50 continue from the heat conductive layer 20 to the backplane layer 40, and a contact area between the heat conductive holes 50 and the backplane layer 40 is increased, accelerating conduction of the heat in the heat conductive holes 50 to the backplane layer 40.

In this embodiment, a material of the heat dissipation columns in the first sub-holes 501 and a material of the heat dissipation columns in the second sub-holes 502 may be same.

In this embodiment, although an arrangement of the second sub-holes 502 may increase a heat exchange area between the heat dissipation columns and the backplane layer 40, however, when contact areas between the second sub-holes 502 and the first sub-holes 501 are smaller, improvement of a heat dissipation effect is limited.

In this embodiment, orthographic projections of the second sub-holes 502 on the first sub-holes 501 may be located in the first sub-holes 501, that is, circumscribed areas of the second sub-holes 502 are the contact areas between the second sub-holes 502 and the first sub-holes 501.

In this embodiment, the substrate layer 10 is generally an insulating substrate with poor heat conductivity, although an arrangement of the first sub-holes 501 may improve the heat dissipation effect of the display backplane 100, however, since an overall heat dissipation effect of the second sub-holes 502 and the backplane layer 40 is greater than an overall heat dissipation effect of the first sub-holes 501 and the substrate layer 10, that is, the heat conducted from the first sub-holes 501 to the second sub-holes 502 and the backplane layer 40 is less than the heat exported from the second sub-holes 502 and the backplane layer 40.

In the display backplane 100 of the present disclosure, outer diameters of the first-sub holes 501 may be greater than outer diameters of the second sub-holes 502. Referring to FIG. 4, the outer diameters of the first-sub holes 501 are greater than the outer diameters of the second sub-holes 502, that is, the heat in the first sub-holes 501 is not only conducted to the second sub-holes 502, but part of the heat is also conducted to the backplane layer 40, heat conduction efficiency of the first sub-holes 501 is increased, the heat conducted by the heat dissipation columns in the first sub-holes 501 to the second sub-holes 502 and the backplane layer 40 in a unit time and the heat exported by the second sub-holes 502 and the backplane layer 40 in the unit time are as equal as possible to maximize the heat conduction efficiency of the display backplane 100.

In the display backplane 100 of the present disclosure, a thermal conductivity of each of the heat dissipation columns in the first sub-holes 501 is greater than the thermal conductivity of each of the heat dissipation columns in the second sub-holes 502.

In this embodiment, the thermal conductivity of each of the heat dissipation columns in the first sub-holes 501 is adjusted to increase heat conduction from the heat dissipation columns in the first sub-holes 501 to the second sub-holes 502 and the backplane layer 40 in the unit time, so that the heat conducted by the heat dissipation columns in the first sub-holes 501 to the second sub-holes 502 and the backplane layer 40 in the unit time and the heat exported by the second sub-holes 502 and the backplane layer 40 in the unit time are as equal as possible to maximize the heat conduction efficiency of the display backplane 100.

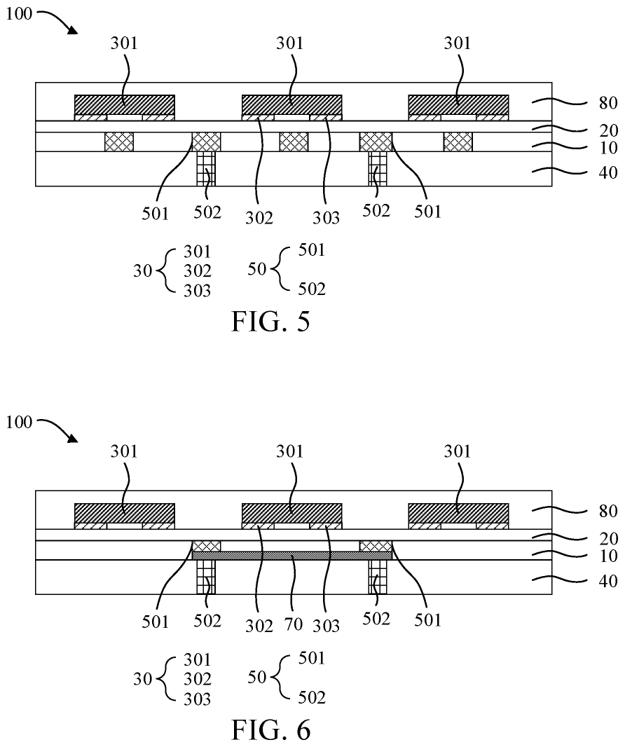

In the display backplane 100 of the present disclosure, referring to FIG. 5, a number of the first sub-holes 501 is greater than a number of the second sub-holes 502.

In this embodiment, the number of the first sub-holes 501 is increased to increase heat conduction of the heat conductive layer 20 to the second sub-holes 502 and the backplane layer 40 through the first sub-holes 501 in the unit time, so that the heat conducted by the heat dissipation columns in the first sub-holes 501 to the second sub-holes 502 and the backplane layer 40 in the unit time and the heat exported by the second sub-holes 502 and the backplane layer 40 in the unit time are as equal as possible to maximize the heat conduction efficiency of the display backplane 100.

In above-mentioned embodiments, the outer diameters of the first sub-holes 501, the heat dissipation columns in the first sub-holes 501, and the number of the first sub-holes 501 are all arranged to balance heat exchange between the substrate layer 10 and the backplane layer 40. The above-mentioned three embodiments may be arranged in combination as long as the heat conduction efficiency of the display backplane 100 is ensured to be maximized.

In the display backplane 100 of the present disclosure, referring to FIG. 6, the display backplane 100 may further include a heat dissipation joint part 70, and the heat dissipation joint part 70 may be arranged in contact with adjacent at least two of the first sub-holes 501. Both ends of the heat dissipation joint part 70 are arranged in contact with corresponding ones of the first sub-holes 501, and the heat dissipation joint part 70 is arranged on a surface of a side of the backplane layer 40 adjacent to the substrate layer 10.

In this embodiment, the heat dissipation joint part 70 is in contact with a surface of the backplane layer 40, the heat of the heat conductive layer 20 may be conducted to the heat dissipation joint part 70 through the heat dissipation columns in the first sub-holes 501, and the heat dissipation joint part 70 conducts the heat to the corresponding backplane layer 40 to complete heat conduction.

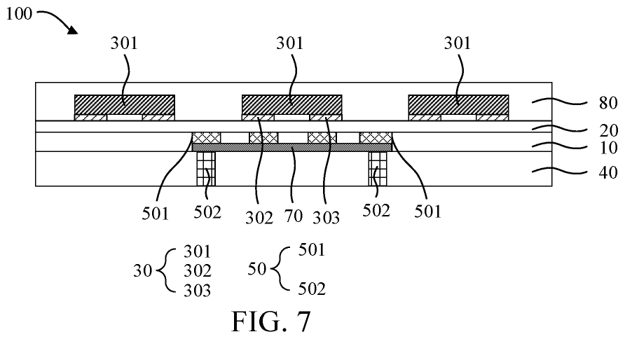

In this embodiment, the heat dissipation joint part 70 may be connected with two of the first sub-holes 501, such as a structure shown in FIG. 6, or a structure shown in FIG. 7. The dissipation joint part 70 may be connected with four of the first sub-holes 501, and a number of the heat dissipation joint part 70 and the number of the first sub-holes 501 are not limited here.

In this embodiment, a material of the heat dissipation joint part 70 and a material of the heat dissipation columns in the first sub-holes 501 may be same, that is, heat conduction between same materials is continuous. Or, a thermal conductivity of the material of the heat dissipation joint part 70 may be greater than the thermal conductivity of the heat dissipation columns in the first sub-holes 501; that is, since the heat dissipation joint part 70 is in direct contact with the backplane layer 40, and a contact area is larger, the thermal conductivity of the material of the heat dissipation joint part 70 is set to be larger, so that the heat conduction in the heat dissipation joint part 70 to the backplane layer 40 may be accelerated, and the heat conduction efficiency of the display backplane 100 may be improved.

In this embodiment, a ratio of a thickness of the heat dissipation joint part 70 to a thickness of the substrate layer 10 is greater than or equal to one-third. An arrangement of the heat dissipation joint part 70 is equivalent to etching the substrate layer 10 into a groove to fill a heat dissipation column in the groove, and the heat dissipation column is connected with the heat dissipation columns in the first sub-holes 501. A maximum ratio of the thickness of the heat dissipation joint part 70 to the thickness of the substrate layer 10 is 1, that is, the thickness of the heat dissipation joint part 70 is equal to the thickness of the substrate layer 10, which is equivalent to the substrate layer 10 being hollowed out, and provided with all the corresponding heat dissipation columns.

When a current display backplane 100 is operated, a certain temperature difference may occur in a central area and a peripheral area of the display backplane 100; that is, a temperature of the display backplane 100 decreases from a center to a periphery. In this embodiment, more of the heat conductive holes 50 may be arranged in the central area of the display backplane 100, and less of the heat conductive holes 50 may be arranged in the peripheral area; that is, a distribution density of the heat conductive holes 50 in the central area of the display backplane 100 is greater than a distribution density of the heat conductive holes 50 in a peripheral area of the display backplane 100, or, from the central area to the peripheral area of the display backplane 100, the distribution density of the heat conductive holes 50 gradually decreases.

The present disclosure further provides a display device including above-mentioned display backplane 100 and a cover layer arranged on the display backplane 100, and the display backplane 100 and the cover layer are combined into a whole.

In this embodiment, the display backplane 100 includes a substrate layer 10, a heat conductive layer 20 arranged on a surface of the substrate layer 10, a light-emitting layer 30 arranged on a surface of the heat conductive layer 20, and a backplane layer 40 arranged on a side of the substrate layer 10 away from the heat conductive layer 20; the substrate layer 10 is arranged in contact with the backplane layer 40.

In this embodiment, the display backplane 100 further includes heat conductive holes 50 at least penetrating through the substrate layer 10, heat dissipation columns are arranged in the heat conductive holes 50, and the heat dissipation columns are in contact with the heat conductive layer 20 and the backplane layer 40, respectively.

In this embodiment, the display device may include electronic devices such as a mobile phone, a television, a notebook computer, etc.

It may be understood that, for those skilled in the art, equivalent replacements and modifications can be made according to the technical solution and invention ideas thereof of the present disclosure, and all these modifications or replacements are considered within the protection scope of the attached claims of the present disclosure.

What is claimed is:

1. A display backplane, comprising:
a substrate layer;
a heat conductive layer arranged on a surface of the substrate layer;
a light-emitting layer arranged on a surface of the heat conductive layer;
a backplane layer arranged on a side of the substrate layer away from the heat conductive layer; and
heat conductive holes at least penetrating through the substrate layer, wherein heat dissipation columns are arranged in the heat conductive holes, and the heat dissipation columns are in contact with the heat conductive layer and the backplane layer, respectively.

2. The display backplane according to claim 1, wherein the heat conductive holes comprise first sub-holes and second sub-holes, the first sub-holes and the second sub-holes are continuously arranged;
wherein the first sub-holes are defined in the substrate layer, and the second sub-holes are defined in the backplane layer.

3. The display backplane according to claim 2, wherein a thermal conductivity of each of the heat dissipation columns in the first sub-holes is greater than a thermal conductivity of each of the heat dissipation columns in the second sub-holes.

4. The display backplane according to claim 2, wherein outer diameters of the first-sub holes are greater than outer diameters of the second sub-holes.

5. The display backplane according to claim 2, wherein a number of the first-sub holes is greater than a number of the second sub-holes.

6. The display backplane according to claim 2, wherein the display backplane further comprises:
a heat dissipation joint part arranged between adjacent at least two of the first sub-holes, the heat dissipation joint part is arranged in contact with the adjacent at least two of the first sub-holes, and the heat dissipation joint part is arranged on a surface of a side of the backplane layer adjacent to the substrate layer.

7. The display backplane according to claim 6, wherein a ratio of a thickness of the heat dissipation joint part to a thickness of the substrate layer is greater than or equal to one-third.

8. The display backplane according to claim 6, wherein a material of the heat dissipation joint part and a material of the heat dissipation columns in the first sub-holes are same.

9. The display backplane according to claim 1, wherein the light-emitting layer comprises a plurality of lamp areas, a plurality of light-emitting units arranged in an array are arranged in each of the lamp areas;
wherein at least one of the heat conductive holes is arranged in each of the lamp areas.

10. The display backplane according to claim 1, wherein a distribution density of the heat conductive holes in a central area of the display backplane is greater than a distribution density of the heat conductive holes in a peripheral area of the display backplane.

11. The display backplane according to claim 10, wherein from the central area of the display backplane to the peripheral area of the display backplane, the distribution density of the heat conductive holes gradually decreases.

12. A display device, comprising a display backplane and a cover layer arranged on the display backplane; wherein the display backplane comprises:
a substrate layer;
a heat conductive layer arranged on a surface of the substrate layer;
a light-emitting layer arranged on a surface of the heat conductive layer;
a backplane layer arranged on a side of the substrate layer away from the heat conductive layer; and
heat conductive holes at least penetrating through the substrate layer, wherein heat dissipation columns are arranged in the heat conductive holes, and the heat dissipation columns are in contact with the heat conductive layer and the backplane layer, respectively.

13. The display device according to claim 12, wherein the heat conductive holes comprise first sub-holes and second sub-holes, the first sub-holes and the second sub-holes are continuously arranged;
wherein the first sub-holes are defined in the substrate layer, and the second sub-holes are defined in the backplane layer.

14. The display device according to claim 13, wherein the display backplane further comprises:
a heat dissipation joint part arranged between adjacent at least two of the first sub-holes, the heat dissipation joint part is arranged in contact with the adjacent at least two of the first sub-holes, and the heat dissipation joint part is arranged on a surface of a side of the backplane layer adjacent to the substrate layer.

15. The display device according to claim 14, wherein a ratio of a thickness of the heat dissipation joint part to a thickness of the substrate layer is greater than or equal to one-third.

16. The display device according to claim 13, wherein outer diameters of the first-sub holes are greater than outer diameters of the second sub-holes.

17. The display device e according to claim 13, wherein a thermal conductivity of each of the heat dissipation columns in the first sub-holes is greater than a thermal conductivity of each of the heat dissipation columns in the second sub-holes.

18. The display device according to claim 12, wherein the light-emitting layer comprises a plurality of lamp areas, a plurality of light-emitting units arranged in an array are arranged in each of the lamp areas;
wherein at least one of the heat conductive holes is arranged in each of the lamp areas.

19. The display device according to claim 12, wherein a distribution density of the heat conductive holes in a central area of the display backplane is greater than a distribution density of the heat conductive holes in a peripheral area of the display backplane.

20. The display device according to claim 19, wherein from the central area of the display backplane to the peripheral area of the display backplane, the distribution density of the heat-conductive holes gradually decreases.
